(19) United States
(12) Patent Application Publication
(10) Pub. No.: US 2024/0195414 A1
(43) Pub. Date: Jun. 13, 2024

(54) SUPERCONDUCTING CURRENT CONTROL SYSTEM

(71) Applicants: CODY JAMES BALLARD, Catonsville, MD (US); JOEL D. STRAND, Ellicott City, MD (US); THOMAS BERNHARD CHAMBERLIN, Baltimore, MD (US)

(72) Inventors: CODY JAMES BALLARD, Catonsville, MD (US); JOEL D. STRAND, Ellicott City, MD (US); THOMAS BERNHARD CHAMBERLIN, Baltimore, MD (US)

(73) Assignee: NORTHROP GRUMMAN SYSTEMS CORPORATION, FALLS CHURCH, VA (US)

(21) Appl. No.: 18/063,518

(22) Filed: Dec. 8, 2022

(51) Int. Cl. H03K 17/92; H02M 3/04

(52) U.S. Cl. CPC H03K 17/92; H02M 3/04

(57) ABSTRACT

One example includes a superconducting current control system. The system includes an inductive coupler comprising a load inductor and a control inductor. The inductive coupler can be configured to inductively provide a control current from the control inductor to a superconducting circuit device based on a load current being provided through the load inductor. The system also includes a current control element comprising a superconducting quantum interference device (SQUID) array comprising a plurality of SQUIDs. The current control element can be coupled to the inductive coupler to control an amplitude of the load current through the load inductor, and thus to control an amplitude of the control current to the superconducting circuit device.

### GOVERNMENT INTEREST

The invention was made under Government Contract. Therefore, the US Government has rights to the invention as specified in that contract.

### TECHNICAL FIELD

This disclosure relates generally to classical and superconducting computing systems, and more specifically to a superconducting current control system.

### BACKGROUND

In a variety of different types of superconducting circuits, control loops are typically implemented to provide operational power to a given circuit via dynamic flux. The flux control can be delivered via a current flowing through a load inductor that is coupled to a current loop that includes a given superconducting circuit. The load inductor can be coupled to the current loop via an inductive coupling that implements a mutual inductance. To provide a sufficient amount of current to the superconducting circuit, a superconducting digital-to-analog converter (DAC) can be coupled to the load inductor to tune the current amplitude to the superconducting circuit. The DAC can thus be adjusted during a calibration process to provide the sufficient amplitude of the current to the superconducting circuit.

### SUMMARY

One example includes a superconducting current control system. The system includes an inductive coupler comprising a load inductor and a control inductor. The inductive coupler can be configured to inductively provide a control current from the control inductor to a superconducting circuit device based on a load current being provided through the load inductor. The system also includes a current control element comprising a superconducting quantum interference device (SQUID) array comprising a plurality of SQUIDs. The current control element can be coupled to the inductive coupler to control an amplitude of the load current through the load inductor, and thus to control an amplitude of the control current to the superconducting circuit device.

Another example includes a method for controlling an amplitude of a control current provided to a superconducting circuit device. The method includes coupling the superconducting circuit device to a current control element via an inductive coupler. The current control element includes a SQUID array comprising a plurality of radio frequency (RF) SQUIDs. Each of the SQUIDs can be inductively coupled to a bias line. The method also includes providing an input current to the current control element and a load current associated with the inductive coupler to inductively provide the control current from a control inductor associated with the inductive coupler. The method further includes providing a bias current on the bias line to control an amplitude of the load current through the load inductor based on an amplitude of the bias current.

Another example includes a superconducting current control system. The system includes an inductive coupler comprising a load inductor and a control inductor. The inductive coupler can be configured to inductively provide a control current from the control inductor to a superconducting circuit device based on a load current being provided through the load inductor as a first portion of an input current that is received at an input of the superconducting current control system. A second portion of the input current can be provided parallel with the first portion. The system further includes a current control element comprising a first SQUID array and a second SQUID array arranged in parallel between a first terminal and a second terminal. Each of the first and second SQUID array includes a plurality of RF SQUIDs. Each of the RF SQUIDs can be inductively coupled to a bias line configured to conduct a bias current. The current control element can be coupled to the inductive coupler via at least one of the first and second terminals to control an amplitude of the load current through the load inductor based on an amplitude of the bias current. The control current can have an amplitude that is based on the amplitude of the load current.

### BRIEF DESCRIPTION OF THE DRAWINGS

FIG. 1 illustrates an example of a superconducting current control system.

FIG. 2 illustrates an example of a current control element.

FIG. 3 illustrates an example of a SQUID array.

FIG. 4 illustrates another example of a SQUID array.

FIG. 5 illustrates another example of a SQUID array.

FIG. 6 illustrates an example of a timing diagram.

FIG. 7 illustrates another example of a superconducting current control system.

FIG. 8 illustrates yet another example of a superconducting current control system.

FIG. 9 illustrates yet another example of a superconducting current control system.

FIG. 10 illustrates yet another example of a superconducting current control system.

FIG. 11 illustrates an example of a method for controlling an amplitude of a control current provided to a superconducting circuit device.

### DETAILED DESCRIPTION

This disclosure relates generally to classical and superconducting computing systems, and more specifically to a superconducting current control system. The current control system can be implemented in any of a variety of classical and/or superconducting computer systems that may require providing a control current to a superconducting circuit device, such as to tune the control current to a sufficient optimal amplitude. For example, the superconducting current control system can be implemented to tune the amplitude of the control current to the sufficient optimal amplitude during calibration of the superconducting circuit device. The superconducting current control system can include an inductive coupler that includes a load inductor and a control inductor arranged with a mutual inductance with respect to each other. The load inductor can be configured to conduct a load current that is a portion of an input current provided to the superconducting current control system, thus inductively providing the control current via the control inductor to the superconducting circuit device. The control current therefore has an amplitude that is controlled based on an amplitude of the load current.

The superconducting current control system further includes a current control element that is coupled to the load inductor of the inductive coupler. The current control element can include an array of superconducting quantum interference devices (SQUIDs), such as radio frequency (RF) SQUIDs, arranged to conduct a portion of the input current to control the amplitude of the load current. Each of the SQUIDs can be separate inductively coupled to a bias line that is configured to provide a bias current. The bias current can have an amplitude that can control an amount of flux of each SQUID in the SQUID array to control an inductance of the current control element. The bias current can therefore be provided at a very small amplitude to provide sufficient tuning of the inductance of the inductive path provided by the current control element. As an example, based on the small amplitude of the bias current, the current source for the bias current (e.g., a digital-to-analog converter) can be included on the same integrated circuit (IC) as the current control element, such as provided in a superconducting cold space.

The input current can be provided as an input to the superconducting current control system. Therefore, the load inductor can be configured to conduct a first portion of the input current to inductively provide the control current. A second portion of the input current can be provided in parallel with the first portion of the input current. For example, the current control element can be arranged in parallel with the load inductor to conduct the second portion of the input current, such that the load inductor conducts the first portion of the input current. As another example, the current control element can be arranged in series with the load inductor, with a current path being arranged in parallel with the series connection of the load inductor and the current control element. Thus, the current control element and the load inductor can conduct the first portion of the input current and the current path can conduct the second portion of the input current. The current path can be provided as a shunt inductor or a second current control element that is separately (e.g., inversely proportionally) tuned relative to the first current control element. Therefore, based on the tuning of the amplitude of the current through the inductive current path of the current control element, the amplitude of the current through the load inductor, and therefore the control current, can be adjusted to a desired amplitude.

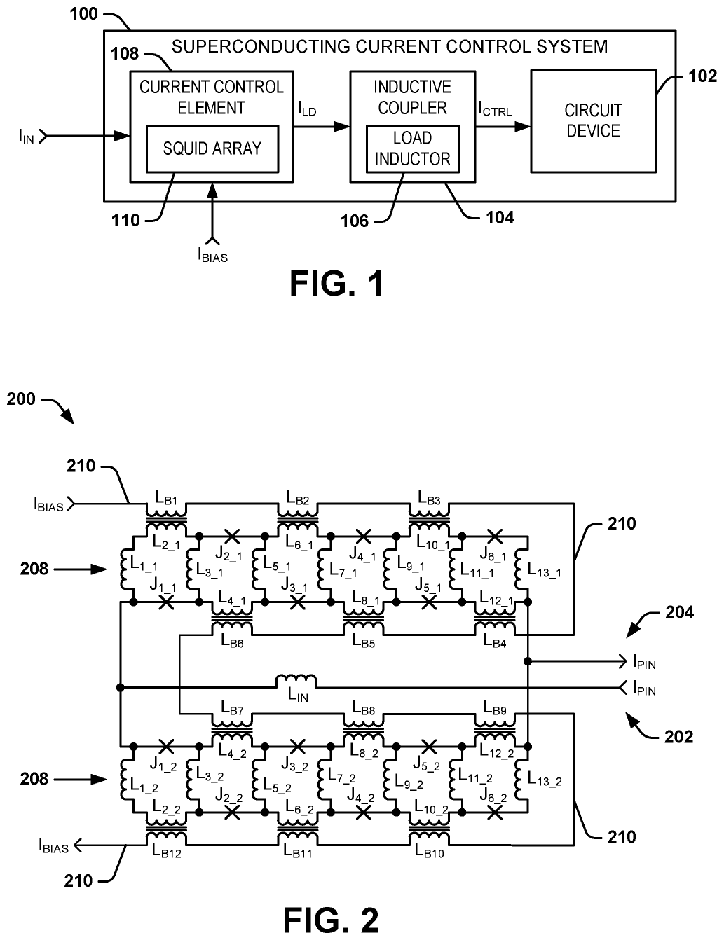

FIG. 1 illustrates an example of a superconducting current control system 100. The superconducting current control system 100 can be implemented in any of a variety of classical and superconducting computer systems that may require providing a control current I_{CTRL} to a superconducting circuit device 102, such as during calibration of the superconducting circuit device 102.

In the example of FIG. 1, the superconducting current control system 100 receives an input current I_{IN} that can have a static current amplitude. The superconducting current control system 100 includes an inductive coupler 104 that can include a load inductor 106 and a control inductor arranged with a mutual inductance with respect to each other. The load inductor 106 can be configured to conduct a load current I_{LD} that is a first portion of the input current I_{IN} provided to the superconducting current control system 100. As a result, the inductive coupler 104 can provide the control current I_{CTRL} via the associated control inductor to the superconducting circuit device 102. The control current I_{CTRL} therefore has an amplitude that is controlled based on an amplitude of the load current I_{LD}. As an example, a second portion of the input current I_{IN} can be provided in parallel with the first portion of the input current I_{IN}, as described in greater detail herein, such that the first and second portions of the input current II have a sum that is equal to the total amplitude of the input current I_{IN}.

The superconducting current control system 100 further includes a current control element 108. The current control element 108 can include an array of superconducting quantum interference devices (SQUIDs) 110, such as radio frequency (RF) SQUIDs, arranged to conduct a portion of the input current I_{IN} to control the amplitude of the load current I_{LD}. For example, the current control element 108 can be coupled to the load inductor 106, such that an inductance of the current control element 108 can be controlled to divert the first portion of the input current I_{IN} through the load inductor 106. In the example of FIG. 1, the current control element 108 receives a bias current I_{BIAS} that has an amplitude that can control an amount of flux of each of the SQUIDs in the SQUID array 110 of the current control element 108, such as to control the inductance of the current control element 108.

As an example, the SQUID array 110 can include a plurality of RF SQUIDs that are arranged in an alternating arrangement along an array. Each of the RF SQUIDs can include a Josephson junction and a pair of inductors that form an inductive path of a portion of the input current I_{IN} that is controlled by the bias current I_{BIAS} to control an amplitude of the load current I_{LD}. For example, the arrangement of the RF SQUIDs in the SQUID array 110 can include two inductive paths in parallel, such that the SQUID array 110 can include two RF SQUID arrays provided in parallel between respective terminals of the current control element 108.

As an example, each of the SQUIDs in the SQUID array 110 can be inductively coupled to a bias line that provides the bias current I_{BIAS}. Therefore, the bias current I_{BIAS} can be inductively provided to each individual SQUID of the SQUID array 110. The bias current I_{BIAS} can therefore be provided at a very small amplitude to provide sufficient tuning of the inductance of the inductive path provided by the current control element 108. As an example, based on the small amplitude of the bias current I_{BIAS}, the current source for the bias current (e.g., a digital-to-analog converter) can be included on the same integrated circuit (IC) as the current control element 108, such as provided in a superconducting cold space.

As described in greater detail herein, the current control element 108 can be arranged in parallel with or in series with the load inductor 106. Therefore, the load inductor 106 can conduct a portion of the input current I_{IN} having an amplitude that can be adjusted to control the amplitude of the control current provided to the superconducting circuit device 102.

FIG. 2 illustrates an example of a current control element 200. The current control element 200 can correspond to the current control element 108 in the example of FIG. 1. Therefore, reference is to be made to the example of FIG. 1 in the following description of the example of FIG. 2.

The current control element 200 includes a first terminal 202 and a second terminal 204. As an example, at least one of the first and second terminals 202 and 204 can be coupled to the inductive coupler 104 in the example of FIG. 1. The first terminal 202 is coupled to an input inductor L_{IN} in a manner that the input inductor L_{IN} is split between each of two SQUID arrays of the current control element 200, as described in greater detail herein. The second terminal 204 is arranged opposite the first terminal 202 with respect to a current path for a portion of the input current, demonstrated as I_{PIN} through the two SQUID arrays. The SQUID arrays are each configured as a plurality of RF SQUIDs 208, with the arrangement of RF SQUIDs 208 being arranged in two parallel alternating array sequences of RF SQUIDs 208 between the first and second terminals 202 and 204. In the example of FIG. 2, each of the SQUID arrays includes a sequence of six RF SQUIDs 208 demonstrated as mirror-images with respect to each other between the first and second terminals 202 and 204. As an example, the quantity of RF SQUIDs can be greater than or less than six to balance increased inductance of the current path through the current control element 200 relative to spatial considerations.

Each of the RF SQUIDs 208 includes a pair of inductors and a Josephson junction. In each of the two N-sequence arrays of RF SQUIDs 208, the inductors are labeled L_{X_Y}, with X corresponding to an index of the respective inductor along the respective array of the RF SQUIDs 208 and with Y corresponding to which of the two arrays of RF SQUIDs 208 in which it is included (e.g., “_1” or “_2”). Similarly, in each of the two N-sequence arrays of RF SQUIDs 208, the Josephson junctions are labeled J_{Z_Y}, with Z corresponding to an index of the respective Josephson junction along the respective array of the RF SQUIDs 208. As an example, all of the Josephson junctions J_{Z} can have an approximately equal critical current I_{C}. In the example of FIG. 2, the first inductor of each of the RF SQUIDs 208, with the exception of the first inductor L₁, is common to a preceding RF SQUID 208 in the sequence of RF SQUIDs 208. The last RF SQUID 208 of each of the arrays includes an additional inductor L₁₃ that is coupled to the second terminal 204. As described herein, in the example of FIG. 2, the inductors L_{X} of the RF SQUIDs 208 of each of the arrays of SQUIDs form an inductive path for half the portion I_{PIN} of the input current (e.g., I_{PIN}/2) between the first and second terminals 202 and 204, with each of the inductive paths being provided through the inductors L_{X_1} and L_{X_2} in parallel with each of the respective Josephson junctions J_{Z_1} and J_{Z_2}. As described in greater detail herein, the flux of each of the RF SQUIDs 208 can be controlled via a direct current (DC) bias current I_{BIAS} to provide a controlled variable inductance between the first and second terminals 202 and 204.

Each of the inductors (L₂, L₄, L₆, L₈, L₁₀, and L₁₂) opposite the Josephson junction in each of the RF SQUIDs 208 is inductively coupled to a bias line 210 that is configured to provide the bias current I_{BIAS}. In the example of FIG. 2, the inductor L_{2_1} forms a transformer with an inductor L_{B1}, the inductor L_{6_1} forms a transformer with an inductor L_{B2}, and the inductor L_{10_1} forms a transformer with an inductor L_{B3}. As demonstrated in the example of FIG. 2, the bias line 210 wraps around the arrays of RF SQUIDs 208 with respect to itself. Therefore, the inductor L_{12_1} forms a transformer with an inductor L_{B4}, the inductor L_{8_1} forms a transformer with an inductor L_{B5}, and the inductor L_{4_1} forms a transformer with an inductor L_{B6}. Similarly, the inductor L_{4_2} forms a transformer with an inductor L_{B7}, the inductor L_{8_2} forms a transformer with an inductor L_{B8}, and the inductor L_{12_2} forms a transformer with an inductor L_{B9}, the inductor L_{10_2} forms a transformer with an inductor L_{B10}, the inductor L_{6_2} forms a transformer with an inductor L_{B11}, and the inductor L_{2_2} forms a transformer with an inductor L_{B12}. Therefore, in the current control element 200, each of the RF SQUIDs 208 is individually biased an equal amount by the bias current I_{BIAS}, thereby providing an approximately equal flux in each of the RF SQUIDs 208.

As described previously, the current control element 200 is demonstrated as being formed as two arrays of RF SQUIDs, with each of the six stages of each of the arrays being composed of a Josephson junction J_{Z} having a critical current I_{C} shunted by the respective linear inductors L_{X}. Therefore, the inductance of the two arrays in parallel, and the flux derivative L′_{T}(Φ_{ac}), can be expressed as:

$${L}_{T} ( {δ}_{0} ( {Φ}_{dc} ) ) = \frac{N}{2} \frac{( {L}_{1} + {L}_{2} ) {L}_{J} + {L}_{1} {L}_{2} cos {δ}_{0}}{{L}_{J} + ( 4 {L}_{1} + {L}_{2} ) cos {δ}_{0}} \qquad Equation 1$$

$${L}_{{T}^{′}} ( {δ}_{0} ( {Φ}_{dc} ) ) = \frac{{( 2 {L}_{1} + {L}_{2} )}^{3} {L}_{J}^{2} {πsinδ}_{0}}{2 {{Φ}_{0} [ ( {L}_{1} + {L}_{2} ) {L}_{J} + {L}_{1} {L}_{2} cos {δ}_{0} ] [ {L}_{J} + ( 4 {L}_{1} + {L}_{2} ) cos {δ}_{0} ]}^{2}} \qquad Equation 2$$

$${L}_{J} = ℏ / 2 {eI}_{c} \qquad Equation 3$$

Where: Φ₀ is a flux quantum, and δ₀(Φ_{dc}) can be expressed as:

$$( \frac{1}{{L}_{1}} + \frac{1}{{L}_{2}} ) {δ}_{0} + \frac{1}{{L}_{J}} sin {δ}_{0} = \frac{{πΦ}_{dc}}{N {Φ}_{0}} ( \frac{1}{{L}_{1}} + \frac{2}{{L}_{2}} ) \qquad Equation 4$$

Therefore, Equations 1-4 demonstrate how the inductance of the current control element 200 can be controlled by the bias current I_{BIAS} to provide an inductive current path for a portion of the input current I_{IN}.

As a result of the arrangement of the current control element 200, the current control element 200 can be implemented to set the current amplitude of the load current I_{LD} through the load inductor 106 to set the amplitude of the control current I_{CTRL} that is inductively provided to the superconducting circuit device 102 via the inductive coupler 104. The arrangement of the array of RF SQUIDs 208 in the current control element 200 can be such that the Josephson junctions J_{Z} are prohibited from triggering to provide a hysteretic effect. In providing an inductive current path for the portion I_{PIN} of the input current, hysteretic behavior of the RF SQUIDs resulting from triggering of the Josephson junctions J_{Z} would provide for undesirable behavior as the triggering of the Josephson junctions J_{Z} would interfere with the amplitude of the portion I_{PIN} of the input current. Therefore, each of the RF SQUIDs 208 can be designed such that the ratio BL, corresponding to a ratio of the geometric inductance of the inductors L_{X} over the Josephson inductance of the Josephson junctions J_{Z} can be less than one.

As a result, as described herein, the current control element 200 can operate to control the amplitude of the load current I_{LD}, and thus the control current I_{CTRL}, without exhibiting hysteretic behavior, as opposed to typical current control methods that implement a simple SQUID to provide an inductive current path for the input current I_{IN}. Accordingly, the current control element 200 can operate with a significantly higher dynamic range relative to typical current control methods that implement a single SQUID. Furthermore, as described above, because the bias current I_{BIAS} is inductively provided individually to each of the RF SQUIDs 208, the bias current I_{BIAS} can be provided at a very small amplitude to provide sufficient tuning of the inductance of the inductive path provided by the current control element 108, as opposed to a single inductive coupling of a bias current to both of the SQUID arrays, as is provided in other conventional current control systems.

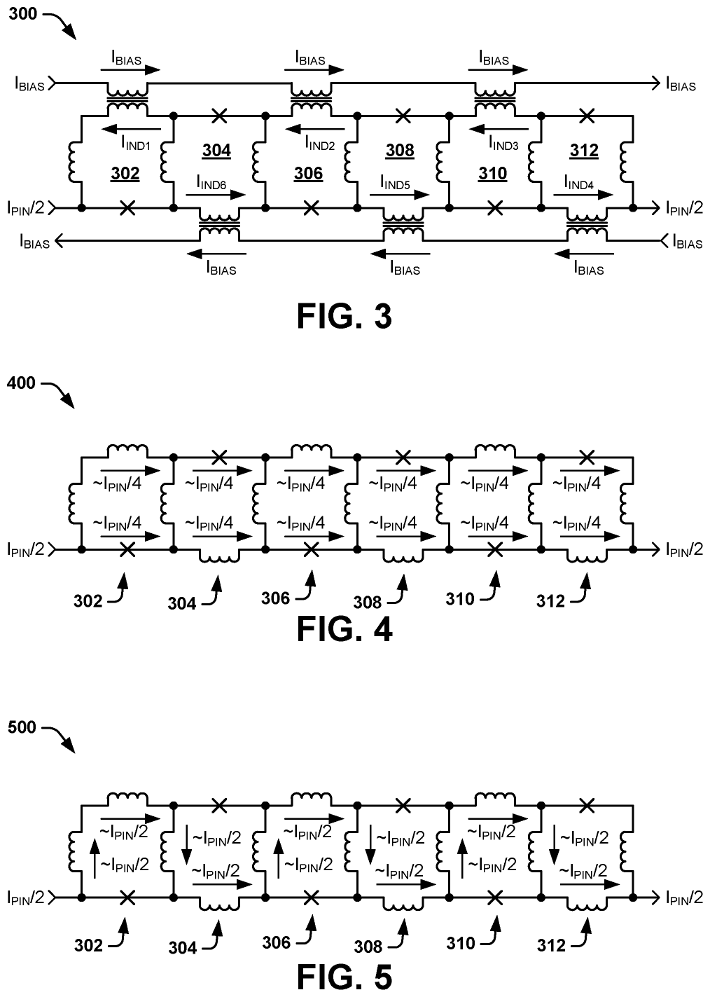

FIG. 3 illustrates an example of a SQUID array 300. The SQUID array 300 can correspond to one of the SQUID arrays of RF SQUIDs 208 in the example of FIG. 2. Therefore, reference is to be made to the example of FIG. 2 in the following description of the example of FIG. 3. Furthermore, the operation of the SQUID array 300 is identical (e.g., mirror-imaged) with respect to the other of the SQUID arrays of the RF SQUIDs 208 in the example of FIG. 2.

The SQUID array 300 is demonstrated as including the six RF SQUIDs demonstrated as a first SQUID 302, a second SQUID 304, a third SQUID 306, a fourth SQUID 308, a fifth SQUID 310, and a sixth SQUID 312. The SQUIDs 302, 304, 306, 308, 310, and 312 each correspond to one of the SQUIDs 208 in the example of FIG. 2, with the descriptors for the inductors and Josephson junctions removed for simplicity. Because the SQUID array 300 corresponds to one of the mirror-image SQUID arrays in the example of FIG. 2, half of the portion of the input current I_{PIN}/2 is demonstrated as being provided through the SQUID array 300.

In the example of FIG. 3, a portion of the bias line 210 is likewise demonstrated in the example of FIG. 3, including the inductors L_{B1} through L_{B6} that are inductively coupled to the respective RF SQUIDS 208 of the SQUID array 300, as described above in the example of FIG. 2. Therefore, in response to the bias current I_{BIAS} provided through the inductors L_{B1} through L_{B6}, the respective inductors in the RF SQUIDs 208 (e.g., the inductors L_{2_1}, L_{4_1}, L_{6_1}, L_{8_1}, L_{10_1}, and L_{12_1}) induce respective currents in the respective RF SQUIDs 208. In the example of FIG. 3, the induced currents are demonstrated as I_{IND1} for the first SQUID 302, I_{IND2} for the second SQUID 304, I_{IND3} for the third SQUID 306, I_{IND4} for the fourth SQUID 308, I_{IND5} for the fifth SQUID 310, and I_{IND6} for the sixth SQUID 312.

Based on the direction of the current I_{BIAS} relative to the topology of the SQUIDs 302, 304, 306, 308, 310, and 312, the induced currents I_{IND1}, I_{IND2}, I_{IND3}, I_{IND4}, I_{IND5}, and I_{IND6} are each provided in a counter clock-wise direction in the respective SQUIDs 302, 304, 306, 308, 310, and 312. Because the currents in each of the SQUIDs 302, 304, 306, 308, 310, and 312 are provided equally in opposite directions into or from the shared inductors between adjoining SQUIDs, the induced currents I_{IND1}, I_{IND2}, I_{IND3}, I_{IND4}, I_{IND5}, and I_{IND6} can be localized to the respective SQUIDs 302, 304, 306, 308, 310, and 312. Accordingly, the induced currents I_{IND1}, I_{IND2}, I_{IND3}, I_{IND4}, I_{IND5}, and I_{IND6} can be provided in a manner that does not interfere with the portion of the input current I_{PIN}/2 through the SQUID array 300.

FIG. 4 illustrates an example of a SQUID array 400. The SQUID array 400 can correspond to the SQUID array 300 in the example of FIG. 3. Therefore, reference is to be made to the example of FIGS. 2 and 3 in the following description of the example of FIG. 4.

The SQUID array 400 is demonstrated as including the six RF SQUIDs 302, 304, 306, 308, 310, and 312. Additionally, the SQUID array 400 is demonstrated in the example of FIG. 4 as not including the bias line 310 for brevity. The SQUID array 400 is demonstrated by example as providing an inductive current path for the portion of the input current I_{PIN}/2. In the example of FIG. 4, the amplitude of the bias current I_{BIAS} can be approximately zero, such as to provide a minimum (e.g., zero) flux in each of the respective SQUIDs 302, 304, 306, 308, 310, and 312.

Therefore, the portion I_{PIN}/2 can have a maximum amplitude based on being provided with a low-inductance current path through the SQUID array 400. Particularly, in the example of FIG. 4, the portion I_{PIN}/2 of the input current can be approximately equally divided between the Josephson junctions J_{Z} and the inductors opposite the Josephson junctions J_{Z} (e.g., the inductors L_{2_1}, L_{4_1}, L_{6_1}, L_{8_1}, L_{10_1}, and L_{12_1}) as currents I_{PIN}/4 from one end of the SQUID array 400 to the opposite end of the SQUID array 400. Thus, very little (e.g., approximately zero) current flows through the inductors interconnecting the Josephson junctions J_{Z} and the inductors opposite the Josephson junctions J_{Z}. Accordingly, by providing a maximum of the first portion of the input current I_{IN} through the current control element 200, the load current I_{LD} is provided accordingly through the load inductor 106 at either a minimum amplitude or a maximum amplitude. As a result, the control current I_{CTRL} can be provided at a likewise minimum or maximum, depending on the topology of the superconducting current control system 100, as explained in greater detail herein.

FIG. 5 illustrates an example of a SQUID array 500. The SQUID array 500 can correspond to the SQUID array 300 in the example of FIG. 3. Therefore, reference is to be made to the example of FIGS. 2 and 3 in the following description of the example of FIG. 5.

The SQUID array 500 is demonstrated as including the six RF SQUIDs 302, 304, 306, 308, 310, and 312. Additionally, the SQUID array 500 is demonstrated in the example of FIG. 5 as not including the bias line 310 for brevity. The SQUID array 500 is demonstrated by example as providing an inductive current path for the portion of the input current I_{PIN}/2. In the example of FIG. 5, the amplitude of the bias current I_{BIAS} can be sufficient to provide a flux in each of the RF SQUIDs 302, 304, 306, 308, 310, and 312 of approximately Φ₀/2, thereby corresponding to a maximum inductance of each of the Josephson junctions J₁, J₂, J₃, J₄, J₅, and J₆ in the respective SQUIDs 302, 304, 306, 308, 310, and 312.

Therefore, the portion I_{PIN}/2 can have a minimum amplitude based on being provided with a high-inductance current path through the SQUID array 500. Particularly, in the example of FIG. 5, the maximum flux of Φ₀/2 provides for a maximum inductance of the Josephson junctions J_{Z}. As a result, approximately the entirety of the portion I_{PIN}/2 of the input current can be provided through each of the inductors L_{X} (e.g., the inductors L_{1_1} through L_{13_1}), and thus steered away from flowing through the high-inductance Josephson junctions J_{Z}, from one end of the SQUID array 500 to the opposite end of the SQUID array 500. Accordingly, by providing a maximum of the first portion of the input current I_{IN} through the current control element 200, the load current I_{LD} is provided accordingly through the load inductor 106 at either a minimum amplitude or a maximum amplitude. As a result, the control current I_{CTRL} can be provided at a likewise minimum or maximum, depending on the topology of the superconducting current control system 100, as explained in greater detail herein.

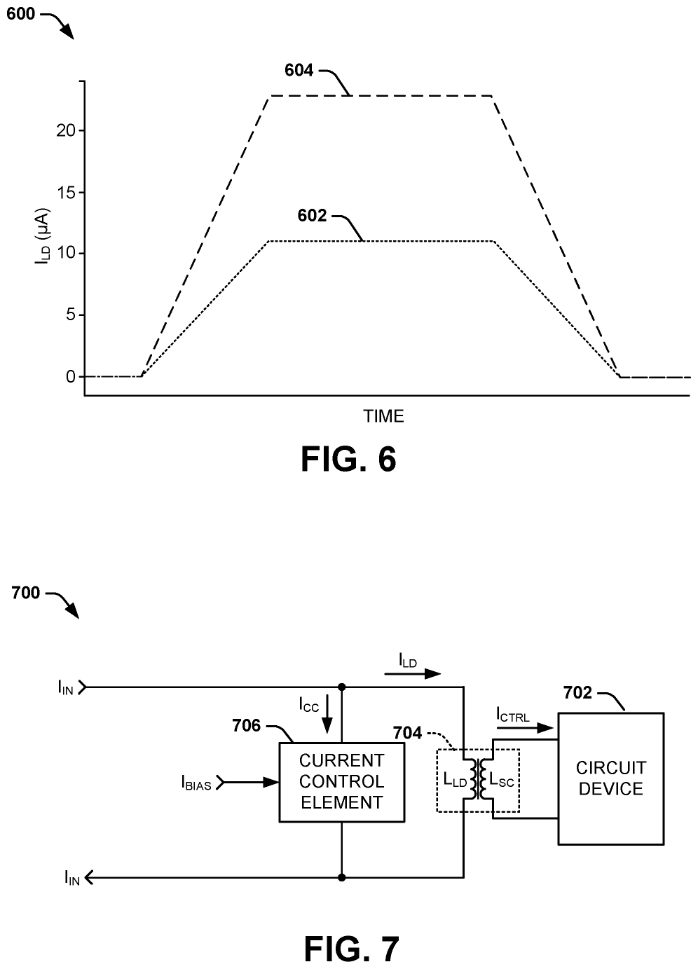

An example of the relative amplitudes of the of the first portion of the input current I_{IN} through the current control element 200 is demonstrated in the example of FIG. 6. FIG. 6 illustrates an example of a timing diagram 600. The timing diagram 600 plots an amplitude of the load current I_{LD} (in μA) as a function of time based on the minimum flux and maximum flux in each of the RF SQUIDs 302, 304, 306, 308, 310, and 312 (and therefore the RF SQUIDs in the other mirror-imaged SQUID array of the current control element 200).

The timing diagram 600 includes a first line 602, demonstrated as a dotted line, that corresponds to a minimum amplitude of the load current I_{LD}, and therefore a minimum amplitude of the control current I_{CTRL}. In the example of FIG. 6, the first line 602 is demonstrated as having a maximum amplitude of approximately 10.9 μA for the load current I_{LD}. As an example, the current control element 200 can be arranged parallel with the load inductor 106, such as to divert a second portion of the input current I_{IN} to provide the first portion of the input current I_{IN} as the load current I_{LD} corresponding to the first line 602 through the load inductor L_{LD}. Therefore, the first line 602 can correspond to a minimum amplitude of the load current I_{LD} that can result from providing zero flux in the SQUIDs 302, 304, 306, 308, 310, and 312 (and the mirror-image SQUIDs) based on a bias current I_{BIAS} of approximately zero amps, as demonstrated in the example of FIG. 4.

The timing diagram 600 also includes a second line 604, demonstrated as a dashed line, that corresponds to a maximum amplitude of the load current I_{LD}, and therefore a maximum amplitude of the control current I_{CTRL}. In the example of FIG. 6, the second line 604 is demonstrated as having a maximum amplitude of approximately 22.7 μA for the load current I_{LD}. As described above, the current control element 200 can be arranged parallel with the load inductor 106 to divert a second portion of the input current II to provide the first portion of the input current I_{IN} as the load current I_{LD}. Therefore, the second line 604 can correspond to a maximum amplitude of the load current I_{LD} that can result from providing Φ₀/2 flux in the SQUIDs 302, 304, 306, 308, 310, and 312 (and the mirror-image SQUIDs) based on providing sufficient bias current I_{BIAS}, as demonstrated in the example of FIG. 5.

FIG. 7 illustrates an example of a superconducting current control system 700. The superconducting current control system 700 can be implemented in any of a variety of classical and superconducting computer systems that may require providing a control current I_{CTRL} to a superconducting circuit device 702, such as during calibration of the superconducting circuit device 702.

In the example of FIG. 7, the superconducting current control system 700 receives an input current I_{IN} that can have a static current amplitude. As an example, the input current I_{IN} can be provided from a DAC. The superconducting current control system 700 includes an inductive coupler 704, demonstrated in the example of FIG. 7 as a transformer includes a load inductor L_{LD} and a control inductor L_{SC} arranged with a mutual inductance with respect to each other. The superconducting current control system 700 also includes a current control element 706 that is demonstrated in the example of FIG. 7 as being arranged in parallel with the load inductor L_{LD}. Therefore, the current control element 706 is configured to conduct a second portion of the input current I_{IN}, demonstrated as a current I_{CC}, and the load inductor L_{LD} is configured to conduct a load current I_{LD} that is a first portion of the input current I_{IN} (e.g., such that the sum of the current I_{CC} and the load current I_{LD} is approximately equal to the input current I_{IN}). As a result, the control inductor L_{SC} can provide the control current I_{CTRL} to the superconducting circuit device 702 based on an amplitude of the load current I_{LD}.

As an example, the current control element 706 can correspond to the current control element 200 in the example of FIG. 2. Therefore, the current control element 706 can be arranged such that the opposite ends of the load inductor L_{LD} can be coupled to the respective terminals 202 and 204 to provide the parallel arrangement between the current control element 706 and the load inductor L_{LD}. Similar to as described previously, the current control element 706 includes an array of RF SQUIDs arranged to conduct the current I_{CC} to control the amplitude of the load current I_{LD}. In the example of FIG. 7, the current control element 706 receives the bias current I_{BIAS} that has an amplitude that can control an amount of flux of the RF SQUID array of the current control element 706, such as to control the inductance of the current control element 706.

Therefore, the load inductor L_{LD} can conduct the load current I_{LD} having an amplitude that can correspond to the amplitude of the control current I_{CTRL} provided to the superconducting circuit device 702. For example, when the current control element 706 is unbiased (e.g., the bias current I_{BIAS} having an approximately zero amplitude), the current control element 706 can divert approximately half the input current I_{IN} from the load inductor L_{LD} to provide a minimum current amplitude to the load inductor L_{LD} (e.g., the first line 602 of the example of FIG. 6), and can divert a minimum (e.g. approximately one-third) of the input current I_{IN} from the load inductor L_{LD} when approximately maximally biased to provide a maximum current amplitude to the load inductor L_{LD} (e.g., the second line 604 of the example of FIG. 6). Therefore, the current control element 706 can provide a dynamic range of approximately twice the load current I_{LD} between the approximate zero and the approximate full bias conditions.

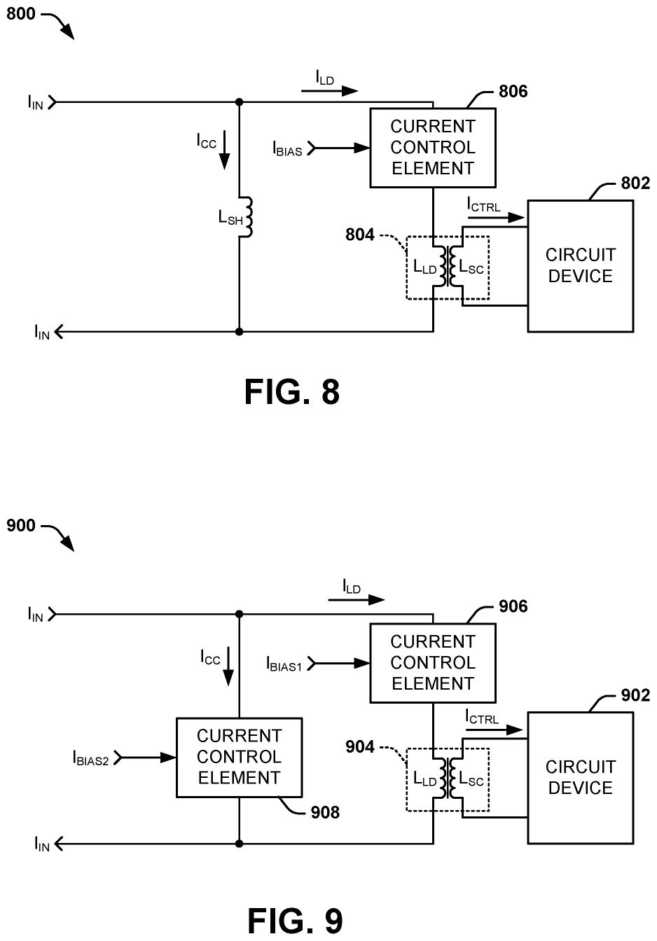

While the example of FIG. 7 demonstrates that the current control element 200 can be arranged in parallel with the load inductor L_{LD}, other arrangements are possible. For example, the current control element 200 can be arranged in series with the load inductor L_{LD} to control the amplitude of the first portion of the input current I_{IN}, and the second portion of the input current I_{IN} can be provided through a current path in parallel with the series connection of the current control element 200 and the load inductor L_{LD}, as demonstrated in the examples of FIGS. 8 and 9.

FIG. 8 illustrates an example of a superconducting current control system 800. The superconducting current control system 800 can be implemented in any of a variety of classical and superconducting computer systems that may require providing a control current I_{CTRL} to a superconducting circuit device 802, such as during calibration of the superconducting circuit device 802.

In the example of FIG. 8, the superconducting current control system 800 receives an input current I_{IN} that can have a static current amplitude. The superconducting current control system 800 includes an inductive coupler 804, demonstrated in the example of FIG. 8 as a transformer includes a load inductor L_{LD} and a control inductor L_{SC} arranged with a mutual inductance with respect to each other. The superconducting current control system 800 also includes a current control element 806 that is demonstrated in the example of FIG. 8 as being arranged in series with the load inductor L_{LD}. The superconducting current control system 800 further includes a shunt inductor L_{SH} that is arranged in parallel with the series arrangement of the current control element 806 and the load inductor L_{LD}. Therefore, the shunt inductor L_{SH} is configured to conduct a current I_{CC} that corresponds to a second portion of the input current II, and the series arrangement of the current control element 806 and the load inductor L_{LD} is configured to conduct a load current I_{LD} that is a first portion of the input current II (e.g., such that the sum of the current I_{CC} and the load current I_{LD} is approximately equal to the input current I_{IN}). As a result, the control inductor L_{SC} can provide the control current I_{CTRL} to the superconducting circuit device 802 based on an amplitude of the load current I_{LD}.

As an example, the current control element 806 can correspond to the current control element 200 in the example of FIG. 2. Therefore, the current control element 806 can be arranged such that the load inductor L_{LD} is coupled to one of the terminals 202 and 204 to provide the series arrangement of the current control element 806 and the load inductor L_{LD}. Similar to as described previously, the current control element 806 includes an array of RF SQUIDs arranged to conduct the load current I_{LD}. In the example of FIG. 8, the current control element 806 receives the bias current I_{BIAS} that has an amplitude that can control an amount of flux of the RF SQUID array of the current control element 806, such as to control the inductance of the current control element 806. Therefore, the current control element 806 and the load inductor L_{LD} can conduct the load current I_{LD} having an amplitude that can correspond to the amplitude of the control current I_{CTRL} provided to the superconducting circuit device 802. For example, when the current control element 806 is unbiased (e.g., the bias current I_{BIAS} having an approximately zero amplitude), the current control element 806 and load inductor L_{LD} can provide a maximum current amplitude to the load inductor L_{LD} (e.g., the second line 604 of the example of FIG. 6), and can provide a minimum current amplitude to the load inductor L_{LD} (e.g., the first line 602 of the example of FIG. 6) when maximally biased.

FIG. 9 illustrates an example of a superconducting current control system 900. The superconducting current control system 900 can be implemented in any of a variety of classical and superconducting computer systems that may require providing a control current I_{CTRL} to a superconducting circuit device 902, such as during calibration of the superconducting circuit device 902.

In the example of FIG. 9, the superconducting current control system 900 receives an input current I_{IN} that can have a static current amplitude. The superconducting current control system 900 includes an inductive coupler 904, demonstrated in the example of FIG. 9 as a transformer includes a load inductor L_{LD} and a control inductor L_{SC} arranged with a mutual inductance with respect to each other. The superconducting current control system 900 also includes a first current control element 906 that is demonstrated in the example of FIG. 9 as being arranged in series with the load inductor L_{LD}. The superconducting current control system 900 further includes a second current control element 908 that is arranged in parallel with the series arrangement of the current control element 906 and the load inductor L_{LD}. Therefore, the second current control element 908 is configured to conduct a current I_{CC} that corresponds to a second portion of the input current I_{IN}, and the series arrangement of the current control element 906 and the load inductor L_{LD} is configured to conduct a load current I_{LD} that is a first portion of the input current I_{IN} (e.g., such that the sum of the current I_{CC} and the load current I_{LD} is approximately equal to the input current I_{IN}). As a result, the control inductor L_{SC} can provide the control current I_{CTRL} to the superconducting circuit device 902 based on an amplitude of the load current I_{LD}.

As an example, the first current control element 906 and the second current control element 908 can each correspond to the current control element 200 in the example of FIG. 2. Therefore, each of the first and second current control elements 906 and 908 include an array of RF SQUIDs, such that the first current control element 906 is arranged to conduct the load current I_{LD} and the second current control element 908 is arranged to conduct the current I_{CC}.

In the example of FIG. 9, the first current control element 906 receives a first bias current I_{BIAS1} that has an amplitude that can control an amount of flux of the RF SQUID array of the first current control element 906, such as to control the inductance of the first current control element 906. Therefore, the first current control element 906 and the load inductor L_{LD} can conduct the load current I_{LD} having an amplitude that can correspond to the amplitude of the control current I_{CTRL} provided to the superconducting circuit device 902. For example, when the first current control element 906 is unbiased (e.g., the bias current I_{BIAS} having an approximately zero amplitude), the first current control element 906 and load inductor L_{LD} can provide a maximum current amplitude to the load inductor L_{LD} (e.g., the second line 604 of the example of FIG. 6), and can provide a minimum current amplitude to the load inductor L_{LD} (e.g., the first line 602 of the example of FIG. 6) when maximally biased.

Similarly, the second current control element 908 receives a second bias current I_{BIAS2} that has an amplitude that can control an amount of flux of the RF SQUID array of the second current control element 908, such as to control the inductance of the second current control element 908. Therefore, the second current control element 908 can conduct the load current I_{CC} to divert the second portion of the input current II from the series arrangement of the first current control element 906 and the load inductor L_{LD}. For example, the first bias current I_{BIAS1} and the second bias current I_{BIAS2} can be inversely proportional to provide inverse flux of the RF SQUID array of the first and second current control elements 906 and 908 with respect to each other. Accordingly, the superconducting current control system 900 in the example of FIG. 9 can achieve a higher dynamic range of the load current I_{LD}, and thus the control current I_{CTRL}.

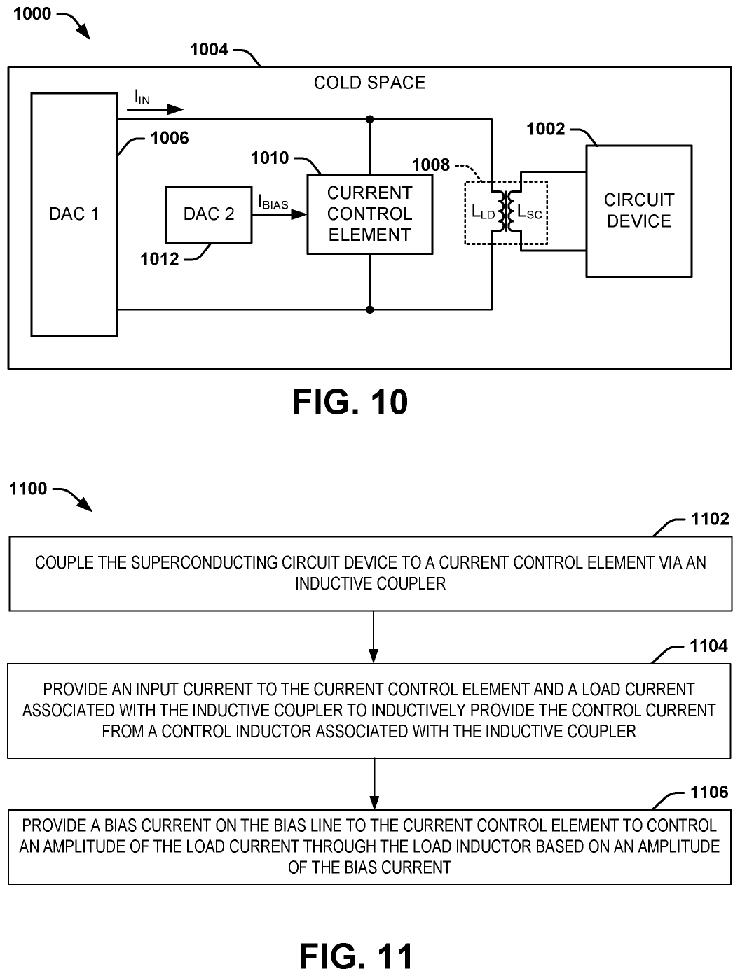

FIG. 10 illustrates an example of a superconducting current control system 1000. The superconducting current control system 1000 can be implemented in any of a variety of classical and superconducting computer systems that may require providing a control current I_{CTRL} to a superconducting circuit device 1002, such as during calibration of the superconducting circuit device 1002.

In the example of FIG. 10, the superconducting current control system 1000 is demonstrated as being provided in a superconducting cold space 1004, such that the ambient operational temperature of the superconducting current control system 1000 can be less than approximately 10 Kelvin. The superconducting current control system 1000 includes a first DAC 1006 that is configured to generate an input current I_{IN}. The superconducting current control system 1000 includes an inductive coupler 1008, demonstrated in the example of FIG. 10 as a transformer includes a load inductor L_{LD} and a control inductor L_{SC} arranged with a mutual inductance with respect to each other. The superconducting current control system 1000 also includes a current control element 1010 that is demonstrated in the example of FIG. 10 as being arranged in parallel with the load inductor L_{LD}. Therefore, similar to as described above in the example of FIG. 7, the current control element 1010 is configured to conduct a second portion of the input current I_{IN}, demonstrated as a current I_{CC}, and the load inductor L_{LD} is configured to conduct a load current I_{LD} that is a first portion of the input current II (e.g., such that the sum of the current I_{CC} and the load current I_{LD} is approximately equal to the input current II). As a result, the control inductor L_{SC} can provide the control current I_{CTRL} to the superconducting circuit device 1002 based on an amplitude of the load current I_{LD}.

As an example, the current control element 1010 can correspond to the current control element 200 in the example of FIG. 2. Therefore, the current control element 1010 can be arranged such that the opposite ends of the load inductor L_{LD} can be coupled to the respective terminals 202 and 204 to provide the parallel arrangement between the current control element 1010 and the load inductor L_{LD}. Similar to as described previously, the current control element 1010 includes an array of RF SQUIDs arranged to conduct the current I_{CC} to control the amplitude of the load current I_{LD}. In the example of FIG. 10, the current control element 1010 receives a bias current I_{BIAS} that has an amplitude that can control an amount of flux of each of the SQUIDs in the RF SQUID array of the current control element 1010, such as to control the inductance of the current control element 1010.

In the example of FIG. 10, the bias current I_{BIAS} is generated by a second DAC 1012. As described above in the example of FIG. 2, each of the SQUIDs in the SQUID array 110 can be inductively coupled to a bias line that provides the bias current I_{BIAS} from the second DAC 1012. Therefore, the bias current I_{BIAS} can be inductively provided to each individual SQUID of the SQUID array of the current control element 1010. As a result, the bias current I_{BIAS} can be provided at a very small amplitude to provide sufficient tuning of the inductance of the inductive path provided by the current control element 1010. Therefore, as demonstrated in the example of FIG. 10, based on the small amplitude of the bias current I_{BIAS}, the second DAC 1012 can be included on the same integrated circuit (IC) as the current control element 1010, such that both the current control element 1010 and the second DAC 1012 can be included in the superconducting cold space 1004.

As an example, a current control element in a conventional superconducting current control system is tuned at a single inductive connection to one or more SQUIDS, which can require a significantly large bias current amplitude. Such a larger bias current amplitude for tuning a current control element thus necessitates providing the bias current from the “room temperature” space outside of the superconducting cold space, which can add additional complexity and cost to the fabrication of the superconducting current control system, as well as additional power consumption. However, by inductively providing the bias current I_{BIAS} to each individual SQUID of the SQUID array of the current control element 1010, the amplitude of the bias current I_{BIAS} enables generation of the bias current I_{BIAS} in the superconducting cold space 1004, thereby mitigating cost, complexity, and power consumption of the superconducting current control system 1000 relative to conventional designs.

In view of the foregoing structural and functional features described above, a methodology in accordance with various aspects of the disclosure will be better appreciated with reference to FIG. 11. FIG. 11 illustrates an example of a method 1100 for controlling an amplitude of a control current provided to a superconducting circuit device. It is to be understood and appreciated that the method of FIG. 11 is not limited by the illustrated order, as some aspects could, in accordance with the present disclosure, occur in different orders and/or concurrently with other aspects from that shown and described herein. Moreover, not all illustrated features may be required to implement a methodology in accordance with an aspect of the present examples.

At 1102, the superconducting circuit device (e.g., the superconducting circuit device 102) is coupled to a current control element (e.g., the current control element 108) via an inductive coupler (e.g., the inductive coupler 104), the current control element comprising a SQUID array (e.g., the SQUID array 110) comprising a plurality of RF SQUIDs (e.g., the SQUIDs 208). Each of the SQUIDs can be inductively coupled to a bias line (e.g., the bias line 210). At 204, an input current (e.g., the input current I_{IN}) is provided to the current control element and a load current (e.g., the load current I_{LD}) associated with a load inductor (e.g., the load inductor L_{LD}) of the inductive coupler to inductively provide the control current (e.g., the control current I_{CTRL}) from a control inductor (e.g., the control inductor L_{SC}) associated with the inductive coupler. At 206, a bias current (e.g., the bias current I_{BIAS}) is provided on the bias line to the current control element to control an amplitude of the load current through the load inductor based on an amplitude of the bias current.

What have been described above are examples of the present invention. It is, of course, not possible to describe every conceivable combination of components or methodologies for purposes of describing the present invention, but one of ordinary skill in the art will recognize that many further combinations and permutations of the present invention are possible. Accordingly, the present invention is intended to embrace all such alterations, modifications and variations that fall within the spirit and scope of the appended claims. Additionally, where the disclosure or claims recite “a,” “an,” “a first,” or “another” element, or the equivalent thereof, it should be interpreted to include one or more than one such element, neither requiring nor excluding two or more such elements. As used herein, the term “includes” means includes but not limited to, and the term “including” means including but not limited to. The term “based on” means based at least in part on.

What is claimed is:

1. A superconducting current control system comprising:
an inductive coupler comprising a load inductor and a control inductor, the inductive coupler being configured to inductively provide a control current from the control inductor to a superconducting circuit device based on a load current being provided through the load inductor; and
a current control element comprising a superconducting quantum interference device (SQUID) array comprising a plurality of SQUIDs, each of the SQUIDs being inductively coupled to a bias line, the bias line being configured to conduct a bias current to control an amplitude of the load current through the load inductor based on an amplitude of the bias current to thereby control an amplitude of the control current to the superconducting circuit device.

2. The system of claim 1, wherein the plurality of SQUIDs are arranged as a plurality of radio frequency (RF) SQUIDs arranged in an array between a first terminal of the SQUID array and a second terminal of the SQUID array, wherein at least one of the first and second terminals is conductively coupled to the inductive coupler.

3. The system of claim 2, wherein the array of RF SQUIDs is arranged as a first array of RF SQUIDs and a second array of RF SQUIDs arranged in parallel between the first and second terminals of the SQUID array.

4. The system of claim 1, wherein each of the plurality of SQUIDs comprises a Josephson junction and an inductor opposite the Josephson junction that is inductively coupled to the bias line, wherein the SQUIDs are arranged in an alternating pattern with respect to the respective Josephson junction and the respective inductor.

5. The system of claim 4, wherein the inductor associated with each of the SQUIDs is a first inductor, each of the SQUIDs comprising a second inductor, the second inductor interconnecting the respective one of the SQUIDs and a previous one of the SQUIDs in the array to provide flux to the respective one of the SQUIDs and the previous one of the SQUIDs in response to an input current, the load current being a portion of the input current.

6. The system of claim 1, further comprising a digital-to-analog converter (DAC) configured to generate the bias current, each of the DAC and the superconducting current control system being arranged in a superconducting cold space.

7. The system of claim 1, wherein the superconducting current control system receives an input current at an input, wherein a first portion of the input current is provided as the load current through the load inductor and a second portion of the input current is provided in parallel with the first portion.

8. The system of claim 7, wherein the current control element is arranged in parallel with the load inductor, wherein the current control element provides a tunable inductive path for the second portion of the input current to control an amplitude of the first portion of the input current as the load current through the load inductor.

9. The system of claim 7, wherein the current control element is arranged in series with the load inductor, the superconducting current control system further comprising a shunt inductor in parallel with the series arrangement of the current control element and the load inductor, wherein the second portion of the input current passes through the shunt inductor and wherein the current control element provides a tunable inductive path for the first portion of the input current to control an amplitude of the first portion of the input current as the load current through the load inductor.

10. The system of claim 7, wherein the current control element is a first current control element arranged in series with the load inductor, the superconducting current control system further comprising a second current control element arranged in parallel with the series arrangement of the first current control element and the load inductor, wherein the first current control element provides a tunable inductive path for the first portion of the input current and the second current control element provides a tunable inductive path for the second portion of the input current to control an amplitude of the first portion of the input current as the load current through the load inductor.

11. A method for controlling an amplitude of a control current provided to a superconducting circuit device, the method comprising:
coupling the superconducting circuit device to a current control element via an inductive coupler, the current control element comprising a superconducting quantum interference device (SQUID) array comprising a plurality of radio frequency (RF) SQUIDs, each of the SQUIDs being inductively coupled to a bias line;
providing an input current to the current control element and a load current associated with a load inductor of the inductive coupler to inductively provide the control current from a control inductor associated with the inductive coupler; and
providing a bias current on the bias line to control an amplitude of the load current through the load inductor based on an amplitude of the bias current.

12. The method of claim 11, wherein each of the plurality of SQUIDs comprises a Josephson junction, a first inductor arranged opposite the Josephson junction and inductively coupled to the bias line, and a second inductor, wherein the RF SQUIDs are arranged in an alternating pattern with respect to the respective Josephson junction and the respective first inductor, and wherein the second inductor interconnects the respective one of the RF SQUIDs and a previous one of the RF SQUIDs in the array to provide flux to the respective one of the RF SQUIDs and the previous one of the RF SQUIDs in response to the input currents.

13. The method of claim 11, wherein the inductive coupler is coupled to the current control element via at least one of a first terminal and a second terminal associated with the current control element, wherein the SQUID array is arranged as a first array of RF SQUIDs and a second array of RF SQUIDs arranged in parallel between the first terminal and the second terminal of the current control element.

14. The method of claim 11, wherein providing the bias current comprises providing the bias current to a transformer associated with the current control element to induce a flux in each of the RF SQUIDs of the SQUID array to control the amplitude of the load current.

15. The method of claim 11, wherein the current control element is arranged in parallel with the load inductor, wherein the current control element provides a tunable inductive path for a first portion of the input current to control an amplitude of a second portion of the input current as the load current through the load inductor.

16. The method of claim 11, wherein the current control element is arranged in series with the load inductor, wherein a current path is arranged in parallel with the series arrangement of the current control element and the load inductor, wherein a first portion of the input current passes through the current path and wherein the current control element provides a tunable inductive path for a second portion of the input current to control an amplitude of the second portion of the input current as the load current through the load inductor.

17. A superconducting current control system comprising:
an inductive coupler comprising a load inductor and a control inductor, the inductive coupler being configured to inductively provide a control current from the control inductor to a superconducting circuit device based on a load current being provided through the load inductor as a first portion of an input current that is received at an input of the superconducting current control system, a second portion of the input current being provided parallel with the first portion; and
a current control element comprising a first superconducting quantum interference device (SQUID) array and a second SQUID array arranged in parallel between a first terminal and a second terminal, each of the first and second SQUID arrays comprising a plurality of RF SQUIDs, each of the RF SQUIDs being inductively coupled to a bias line configured to conduct a bias current, the current control element being coupled to the inductive coupler via at least one of the first and second terminals to control an amplitude of the load current through the load inductor based on an amplitude of the bias current, the control current having an amplitude that is based on the amplitude of the load current.

18. The system of claim 17, wherein each of the plurality of SQUIDs comprises a Josephson junction, a first inductor arranged opposite the Josephson junction and inductively coupled to the bias line, and a second inductor, wherein the RF SQUIDs are arranged in an alternating pattern with respect to the respective Josephson junction and the respective first inductor, and wherein the second inductor interconnects the respective one of the RF SQUIDs and a previous one of the RF SQUIDs in the array to provide flux to the respective one of the RF SQUIDs and the previous one of the RF SQUIDs in response to the input currents.

19. The system of claim 17, wherein the current control element is arranged in parallel with the load inductor, wherein the current control element provides a tunable inductive path for the second portion of the input current to control an amplitude of the first portion of the input current as the load current through the load inductor.

20. The system of claim 17, wherein the current control element is arranged in series with the load inductor, the superconducting current control system further comprising a current path in parallel with the series arrangement of the current control element and the load inductor, wherein the second portion of the input current passes through the current path and wherein the current control element provides a tunable inductive path for the first portion of the input current to control an amplitude of the second portion of the input current as the load current through the load inductor.
